(19) United States
(12) Patent Application Publication
(10) Pub. No.: US 2007/0297135 A1
(43) Pub. Date: Dec. 27, 2007

(54) External heat dissipator detachably adapted to a heat source to force away heat generated by the heat source

(76) Inventor: Chien-Chang Chen, San Chung City (TW)

Correspondence Address: BACON & THOMAS, PLLC, 625 SLATERS LANE, FOURTH FLOOR, ALEXANDRIA, VA, 22314, US

(21) Appl. No.: 11/471,481

(22) Filed: Jun. 21, 2006

(51) Int. Cl. H05K 7/20

(52) U.S. Cl. 361/697

(57) ABSTRACT

An external heat dissipator for a heat generating source having a heat dissipating vent includes a casing adapted to connect to the heat dissipating vent and having an outlet adapted to correspond to and align with the heat generating vent and an inlet communicating with the outlet for allowing air inside the heat generating source to escape therefrom. A fan assembly is securely received in the casing to generate air flow inside the heat generating source for dissipating heat inside the heat generating source. A connection device is provided to engage the casing with the heat dissipating vent of the heat generating source.

### BACKGROUND OF THE INVENTION

1. Field of the Invention

The present invention relates to an external heat dissipator, and more particularly to an external heat dissipator detachably adapted to a heat source so as to force heat generated by the heat source to flow away from the heat source.

2. Description of the Prior Art

Electronic devices have different built-in heat dissipators to force heat generated during the operation of the electrical components inside the electronic device away from the electronic devices to maintain the electrical components in stable working status. If there is no heat dissipator provided inside the electronic device, the electronic device will crash due to overheat. That is, temperature is an important factor in maintaining the electronic device in stable conditions. However, the heat dissipating volume of the built-in heat dissipator can not catch up with the heat generating speed in that in order to meet with multi-task requirements, the advanced electronic devices are somehow provided with dual, high-speed CPUs (central processing unit) to deal with numerous calculations simultaneously.

The rotation speed of each of the two CPUs is becoming faster and faster than ever before so that the operator is able to quickly acquire the required solutions to carry on the next task. It is good to have solutions in just seconds, but it is a big problem as how to maintain the CPU functions normal. As the temperature inside the electronic devices goes higher and higher, the calculation speed of the two CPUs becomes slower and slower. Eventually the electronic devices crash if there is no protection measurements taken to prevent such an incident. U.S. Pat. No. 5,898,568 provides a heat 2 dissipator trying to dissipate as much heat as possible as the CPU is working and the 3 temperature inside the electronic device is building up. However, the efficiency and affect of the heat dissipator disclosed in the patent seems inequitable.

To overcome the shortcomings, the present invention tends to provide an improved external heat dissipator to mitigate the aforementioned problems.

### SUMMARY OF THE INVENTION

The primary objective of the present invention is to provide an external heat dissipator adapted to be detachably connected to a heat generating source so as to force the heat out of a heat generating source.

Other objects, advantages and novel features of the invention will become more apparent from the following detailed description when taken in conjunction with the accompanying drawings.

### BRIEF DESCRIPTION OF THE DRAWINGS

FIG. 1A is an exploded perspective view of the heat dissipator of the present invention;

FIG. 1B is a perspective view of the heat dissipator after being assembled;

FIG. 2 is a partial perspective view of the heat dissipator of the present invention;

FIG. 3 is a schematic top plan view showing the application of the heat dissipator to a side wall of a heat generating source;

FIG. 4 is a schematic top plan view showing that the heat dissipator is securely connected to the side wall of the heat generating source;

FIG. 5 is a schematic perspective view of a second embodiment of the connection device of the present invention;

FIG. 6 is a partially schematic side plan view showing the adaptation of the second embodiment of the connection of the present invention;

FIG. 7 is a schematic perspective view of the third embodiment of the connection device of the present invention; and

FIG. 8 is a schematic perspective view of the fourth embodiment of the connection device of the present invention.

### DETAILED DESCRIPTION OF THE PREFERRED EMBODIMENT

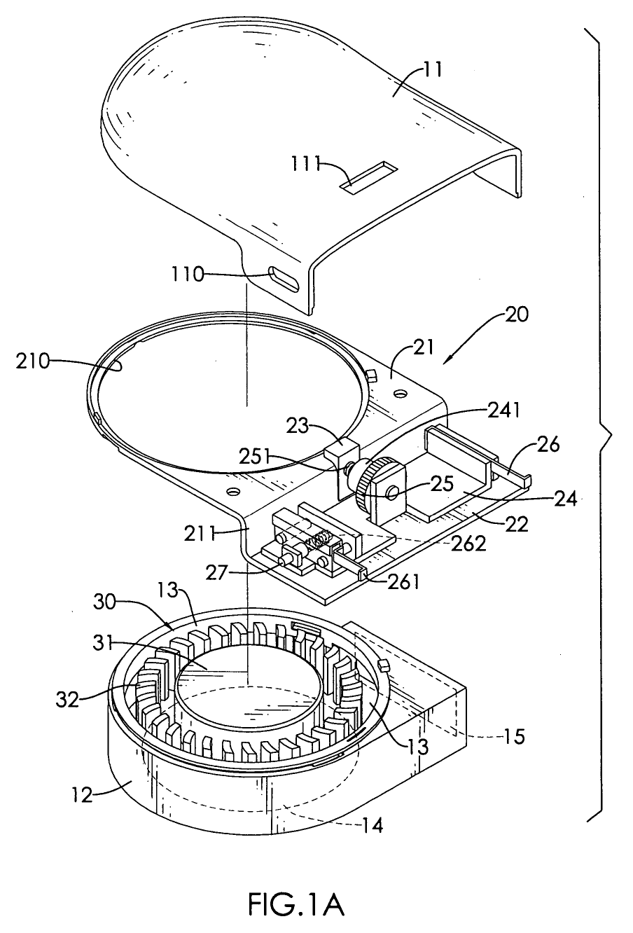

With reference to FIGS. 1A and 1B, it is noted that the external heat dissipator adapted for connection to a heat generating source, e.g. a laptop, and constructed in accordance with the present invention includes a top casing (11), a bottom casing (12), a connection device (20) and a fan assembly (30) rotatably received between the top casing (11) and the bottom casing (12). The top casing (11) has two side holes (110) defined in two opposite side walls of the top casing (11) and a hole (111) defined through a side face between the two opposite side walls of the top casing (11).

The top casing (11) together with the bottom casing (12) defines therebetween a receiving space (13) to receive therein the fan assembly (30). An inlet (14) is defined through a bottom face of the bottom casing (12) and an outlet (15) is defined through a side face of the bottom casing (12) to communicate with the inlet (14) via the receiving space (13). It is well known in the art that the fan assembly (30) normally includes a motor (31) and multiple blades (32) operably controlled by the motor (31) such that when the motor (31) is activated, the blades (32) are able to generate air flow between the top casing (11) and the bottom casing (12).

The connection device (20) in this embodiment includes a base (21) provided with a through hole (210) corresponding to the receiving space (13) of the bottom casing (12) and a step (211) adjacent to the through hole (210). Furthermore, the connection device (20) has a ledge (22) extending from a free end of the step (211) and having a U-shaped seat (23) formed on the ledge (22), a sliding plate (24) movably mounted on top of the ledge (22) and having a sleeve (241) formed on a top face of the sliding plate (24) and situated in a recessed area in the U-shaped seat (23), a knob (25) rotatably received in the recessed area of the U-shaped seat (23) and having a threaded rod (251) threadingly extending through the sleeve (241) as well as the knob (25) and situated between the U-shaped seat (23), a fixed arm (26) formed on one side of the ledge (22), a moving arm (261) movably mounted on a side of the ledge (22) to be opposite to the fixed arm (26), a push (27) movably connected to a side of the moving arm (261) via a spring (262) such that movement of the push (27) drives the moving arm (261) to move accordingly, wherein the push (27) corresponds to the side hole (110) of the top casing (11).

After assembly of the external heat dissipator of the present invention, it is noted that the push (27) is extended out of the side hole (110), the fixed arm (26) as well as the moving arm (261) is extending out of the outlet (15). Further, the knob (250 is extending out of the hole (111) of the top casing (11).

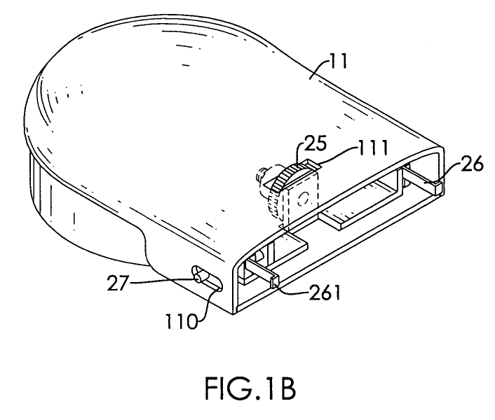

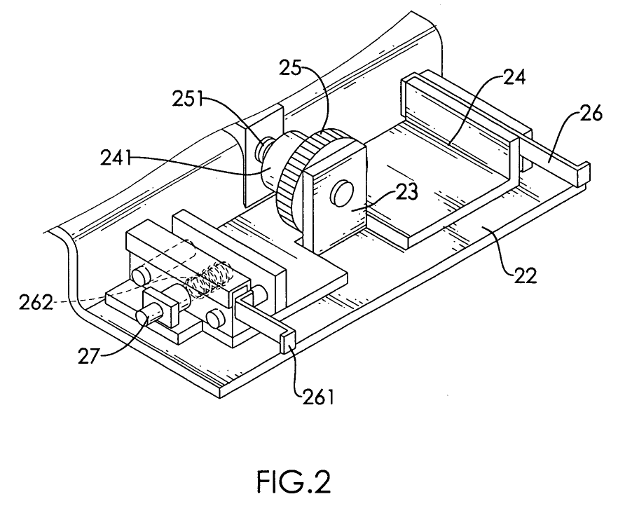

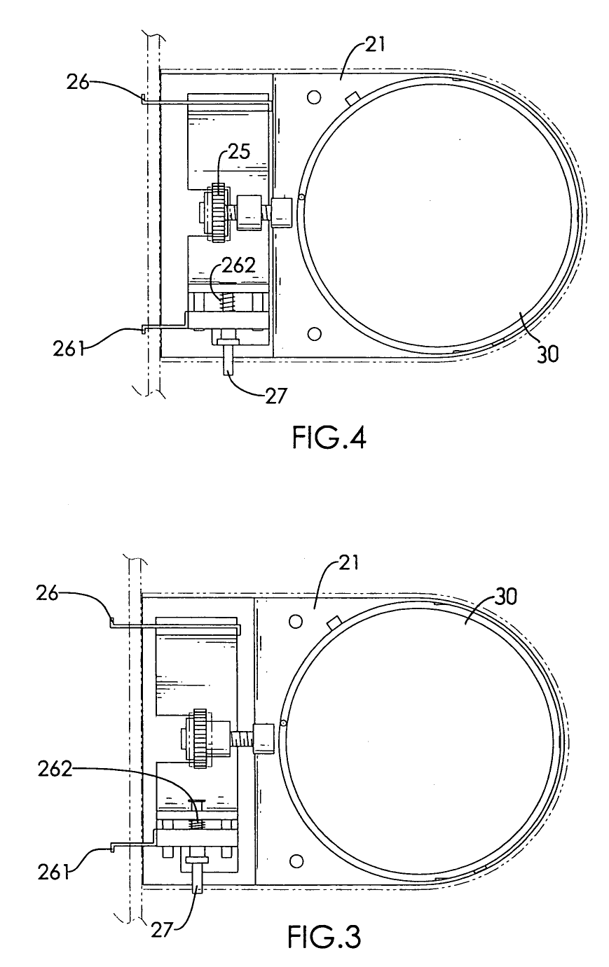

With reference to FIGS. 2, 3 and 4, it is noted that the external heat dissipator of the present invention is adapted to connect to a heat dissipating vent defined in a laptop computer and the heat dissipating vent normally is provided with a grill. Therefore, before the activation of the fan assembly (30), the fixed arm (26) is first extended into the heat dissipating vent (not numbered) of the heat source and then the push (27) is pushed inward to drive the moving arm (261) to move toward the fixed arm (26). After the movement of the moving arm (261), the operator is able to select a suitable void in the heat dissipating vent and then extends the moving arm (261) into a corresponding void. When the push (27) is released, the spring (262) provides a recovery force to the push (27) as well as the moving arm (261) so that the moving arm (261) is able to engage with the peripheral edge of the corresponding void. The fixed arm (26) and the moving arm (261) alone are not able to secure the external heat dissipator to the heat source though they engage with peripheries of the heat source. In order to enhance the engagement with the heat source, the operator rotates the knob (25) to drive the sliding plate (24) to move relative to the ledge (22). Because both the fixed arm (26) and the moving arm (261) are securely mounted on the sliding plate (24), the movement of the sliding plate (24) causes the fixed arm (26) and the moving arm (261) to firmly engage with peripheries of the heat dissipating vent of the heat source (shown in dashed lines). As such, the operation of the fan assembly (30) is able to generate air flow inside the heat source to dissipate the heat inside the heat source.

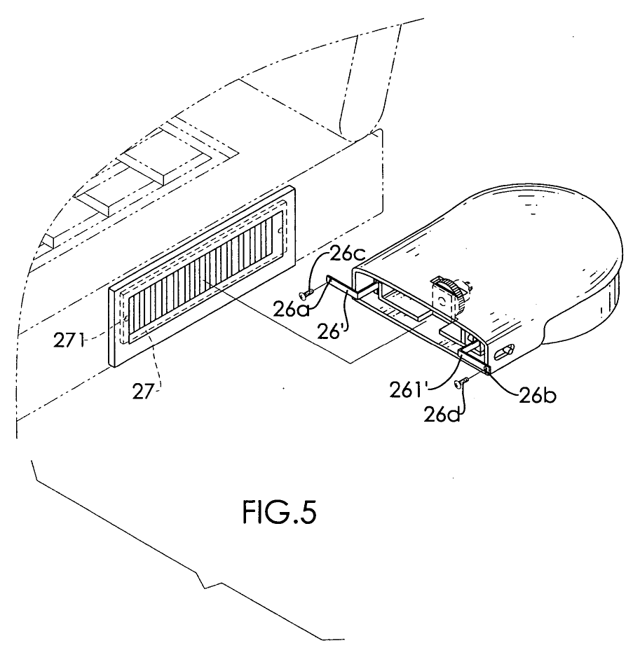

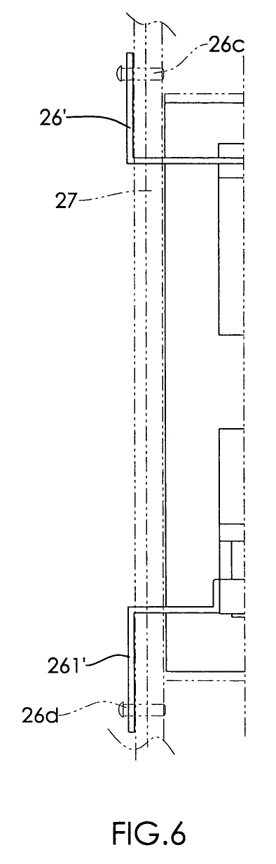

With reference to FIGS. 5 and 6, it is noted that the connection device (20′) in this embodiment now includes a fixed arm (26′) and a moving arm (261′). The structure causing the moving arm (261) to move relative to the fixed arm (26) is the same as that disclosed in the first embodiment. Therefore, detailed description as to how the moving arm (261) is moving relative to the fixed arm (26) is omitted to avoid repetition. Each of the fixed arm (26′) and the moving arm (261′) is provided with a securing hole (26a,26b) and a securing bolt (26c,26d). the connection device (20′) further has a securing plate (27) adapted to be situated behind the heat dissipating vent (shown but not numbered) and having two connection holes (271) corresponding to and aligned with the two securing holes (26a,26b). Thus, when the external heat dissipator is connected to the heat source, the two securing bolts (26c,26d) are threadingly extended into the two securing holes (26a,26b) and the two connection holes (271) of the securing plate (27) to securely connect the external heat dissipator to the heat generating source.

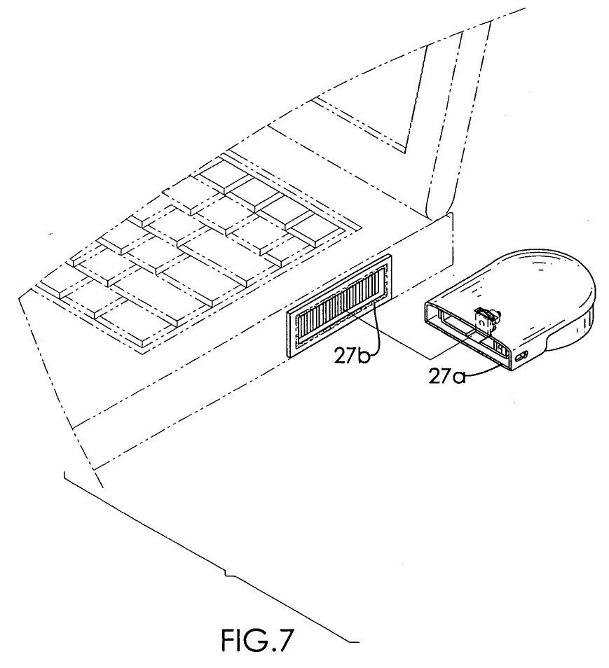

FIG. 7 shows that a male adhesive (27a) and a female adhesive (27b) are respectively provided to a periphery of the outlet (15) of the external heat dissipator of the present invention and a periphery of the heat dissipating vent so that after the male adhesive (27a) and the female adhesive (27b) are connected with each other, the external heat dissipator is securely adapted to connect to the heat generating source.

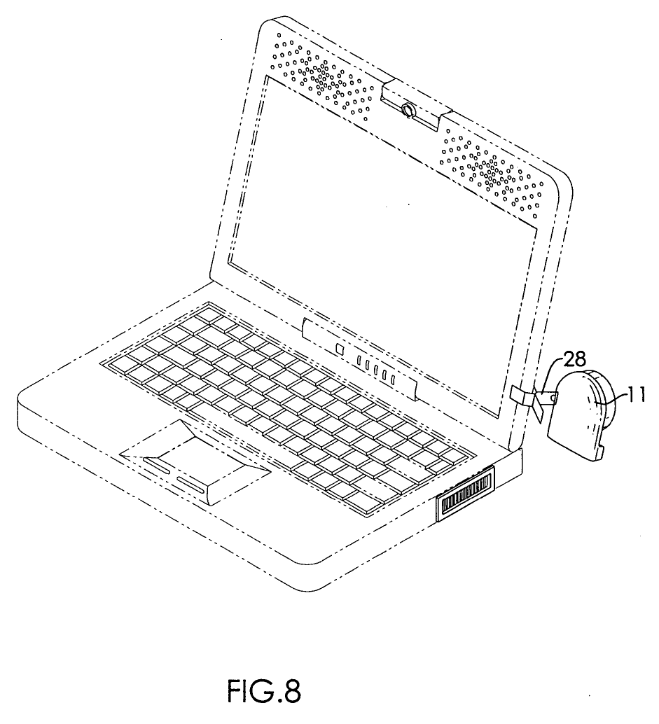

FIG. 8 shows that the connection device of the external heat dissipator of the present invention is a clamp (28) adapted to clamp a periphery of the heat generating source and pivotally connected to a periphery of the top casing (11) such that the external heat generator is able to dissipate heat from the heat generating source after being pivoted to allow engagement between the outlet (15) to communicate with the heat dissipating vent of the heat generating source.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An external heat dissipator for a heat generating source having a heat dissipating vent, the external heat dissipator comprising:
a casing adapted to connect to the heat dissipating vent and having an outlet adapted to correspond to and align with the heat generating vent and an inlet communicating with the outlet for allowing air inside the heat generating source to escape therefrom;
a fan assembly securely received in the casing to generate air flow inside the heat generating source for dissipating heat inside the heat generating source; and
a connection device provided to engage the casing with the heat dissipating vent of the heat generating source.

2. The external heat dissipator as claimed in claim 1, wherein the connection device includes two arms extending out of the outlet of the casing to be adapted to securely engage with a periphery of the heat dissipating vent.

3. The external heat dissipator as claimed in claim 2, the two arms are securely mounted on a sliding plate which is movable relative to the casing.

4. The external heat dissipator as claimed in claim 3 further comprising a base firmly received in the casing and provided with a step and a ledge extending from a free end of the step, the sliding plate being movably mounted on top of the ledge so as to allow the two arms for secured engagement with the periphery of the heat dissipating vent.

5. The external heat dissipator as claimed in claim 4, wherein the base has a U-shaped seat and the ledge has a sleeve integrally formed with the ledge and situated in a recessed area in the U-shaped seat, a threaded rod is rotatably extending through the sleeve and between two opposite sides of the U-shaped seat and a knob is securely mounted on the threaded rod so that rotation of the knob drives the sleeve as well as the sliding plate to move relative to the base and the two arms are able to securely engage with the periphery of the heat dissipating vent.

6. The external heat dissipator as claimed in claim 5, wherein one of the two arms is fixedly mounted on the ledge and the other arm is movable relative to the ledge so that the two arms are able to adapt to the heat dissipating vent.

7. The external heat dissipator as claimed in claim 6, wherein one of the arms is provided with a push engaged with the arm via a spring and extending out of the casing from a side hole which is defined in a side of the casing.

8. The external heat dissipator as claimed in claim 1, wherein the connection device includes a male adhesive securely provided to a periphery of the outlet and a female adhesive adapted to be mounted on the periphery of the heat dissipating vent so that engagement between the male adhesive and the female adhesive allows the periphery of the outlet to connect to the periphery of the heat dissipating vent.

9. The external heat dissipator as claimed in claim 2 further comprising a securing plate adapted to be situated behind the heat dissipating vent and having two connection holes respectively corresponding to and aligning with two securing holes each defined in a corresponding one of the two arms so as to allow two securing bolts to extend into the aligned securing holes and the connection holes to secure engagement between the outlet of the casing and the heat dissipating vent.

10. The external heat dissipator as claimed in claim 1, wherein the connection device is a claim pivotally connect to the periphery of the outlet to allow the casing to be pivoted to engage the periphery of the outlet with the heat dissipating vent.
